(19) United States
(12) Patent Application Publication
(10) Pub. No.: US 2006/0193483 A1
(43) Pub. Date: Aug. 31, 2006

(54) Volume control method and system

(75) Inventor: Karl J. Wood, CRAWLEY (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 10/550,611

(22) PCT Filed: Mar. 16, 2004
(86) PCT No.: PCT/IB04/00871

§ 371 Date: Sep. 23, 2005

(30) Foreign Application Priority Data
Mar. 28, 2003 (GB) 0307183.4

(51) Int. Cl. H03G 3/00

(52) U.S. Cl. 381/105; 381/104; 381/107

(57) ABSTRACT

A method and system enabling a user to request volume control of another users device according to an agreed policy containing criteria is described. A first device receives (60) a radio message from a second device, accesses (62) the policy to determine (64) whether or not (65,66) to adjust (68) the output volume in dependence on the criteria, and acknowledges the message (70). The system and method may be implemented in communal living buildings such as hotels or halls of residence, with the policy centrally maintained. Hence, criteria such as threshold volume levels and quiet periods may be negotiated between users and defined in the policy. Request messages and acknowledgements may be stored in a log and used in the event of repeated disputes concerning loud music and antisocial behaviour between neighbouring device owners.

The present invention relates to a method and system for controlling the output volume of a device in accordance with a stored policy. The present invention has particular, but not exclusive, application to audio-visual devices located in communal buildings comprising individual apartments.

The problem of noise pollution is in general annoying and in particular can be very stressful for those who are subjected to, for example, someone else's choice of music. The right to a quiet enjoyment of one's residence is recognised in some legal jurisdictions as a fundamental right, but enforcing such a right can be problematic from both a peaceful communal co-existence point of view and in providing evidence of habitual noise pollution.

At the time of writing, the only way in which one may control the volume output of a third party or neighbour's device (such as for example an audio device or “Hi-Fi”) typically involves politely requesting verbally to manually adjust the volume output which, even if the request is successful, can lead to soured or poor future relations with the party.

A facility for controlling the volume output of say, a third party or neighbour's device would be useful in such circumstances.

It is therefore an object of the present invention to provide a method and system suitable for controlling the output volume of a third party device in certain circumstances.

According to a first aspect of the present invention there is provided a method for controlling the volume output of a first device, said device being operable to communicate with a second device over a network link, the method comprising the second device sending a message to the first device which receives said message, accesses a stored policy and adjusts said output in dependence on the stored policy.

According to a second aspect of the present invention there is provided a system for controlling the volume output of a first device, said device being operable to communicate with a second device over a network link, the second device having communication means for sending a message to the first device, the first device comprising communication means for receiving the message, and processing means for accessing a stored policy and for controlling said output in dependence on the stored policy.

The aforementioned enables a (second) device to request a change in volume output by another (first) device of a third party. The first device may be in the form of a personal computer (PC) or Hi-Fi sound system, or a television or radio or other such sound outputting device. The second device may also belong to the same class of device as the first device, or may be a remote control device or simply a “request” button installed in a users dwelling within a residence, the button being connected to the residence network.

Generally, whether or not the request to lower the volume is heeded by the receiving device depends primarily on a stored policy. The policy is preferably stored electronically in the form of a data structure comprising criteria against which decisions are made. The criteria may be mandated by the owner of a communal property (for example a University Hall of residence) or may be evolved with the cooperation of the residents at a Hall meeting for example. The policy comprising the criteria is stored preferably in the device receiving the request (for example the Hi-Fi) but may be remotely stored in a buildings network server for instance and accessed by the device when necessary.

Advantageously, the criteria comprise the time of day corresponding to agreed quiet times. A device receiving a request to adjust its volume at a certain time of the day may then comply with the request if the time of day corresponds to an agreed quiet time according to the policy. The request may be ignored by the device if the received time is not defined as an agreed quiet period within the policy.

Furthermore, criteria such as the number of requests (either from the same requester or from different requesters) received in a time interval may be defined in the policy so that repeat requests are either complied with or simply stored to indicate possible unreasonable requests from a particular device.

Furthermore, the device receiving the request may determine its current volume output and compare this with a policy criteria comprising a volume threshold to determine whether it is reasonable to comply with the request or not. The request and response may be acknowledged and stored to help provide electronic evidence in the case of, for example, an ongoing dispute between neighbours.

The policy criteria may be user definable to enable either a mandated or negotiated policy to be utilised in a communal residence. Of course, the network may be in a single home and the parent may set the policy so that the volume output of a device in the home is reduced according to the parents wishes (but not necessarily those of the child using the device).

The communication between devices on the network may be wireless (for example IEEE802.11 standards and protocols) or wired (for example an Ethernet network within the building). Preferably indicating means in the form of visual alerts (blinking light-emitting diode or text message on a networked display) are included in the devices to indicate to an owner of a device that a request has been received for example.

Hence, a policy may be agreed upon between device owners living in close proximity to each other, and the policy implemented. Data concerning requests made may be stored to provide evidence in the case of repeated disagreement. The policy may enforce automatic volume control (if agreed) to avoid repeated disagreement.

Further aspects according to the present invention include a device for use with the system and program code for implementing a method thereon.

The present invention will now be described, by way of example only, and with reference to the accompanying drawings wherein:

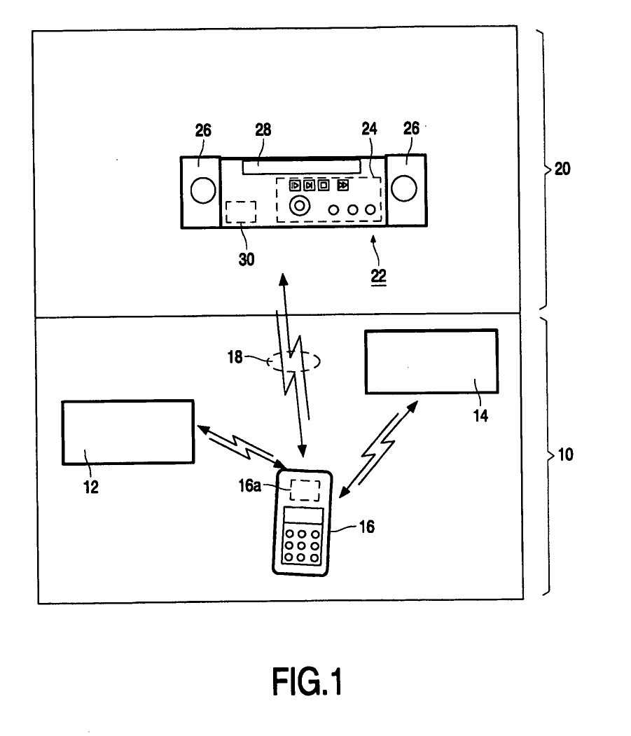

FIG. 1 is a diagram of a dwelling containing devices,

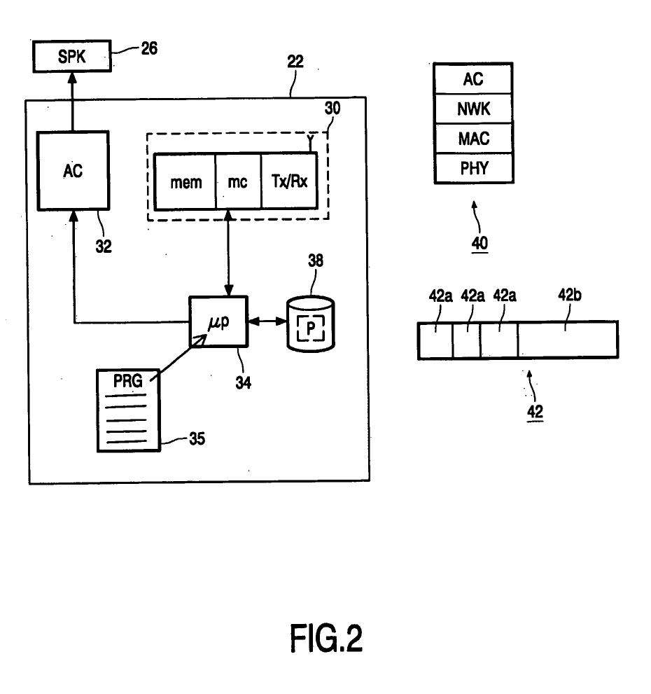

FIG. 2 is a block diagram of a radio controllable device incorporating a policy,

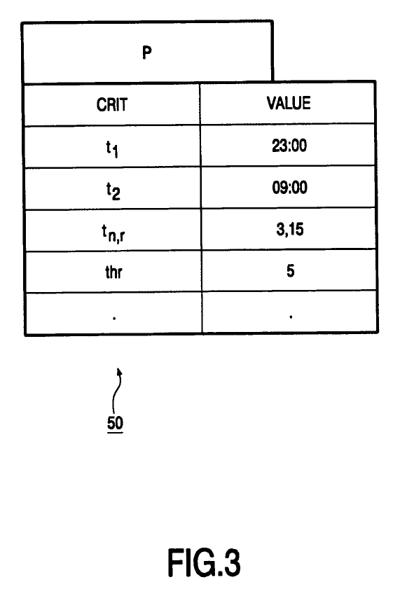

FIG. 3 is an example policy data structure,

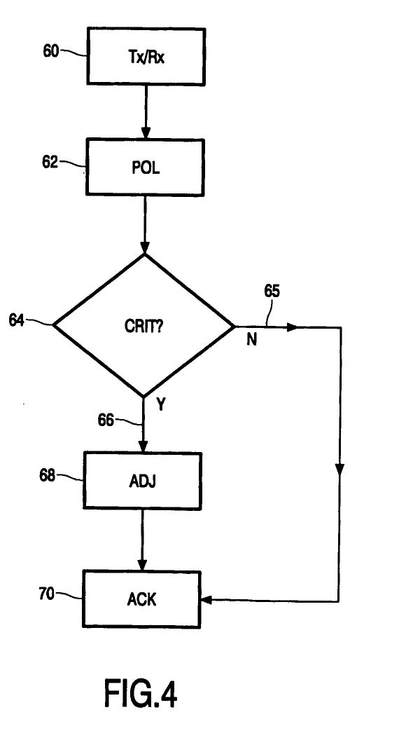

FIG. 4 is a flowchart illustrating steps of a control method,

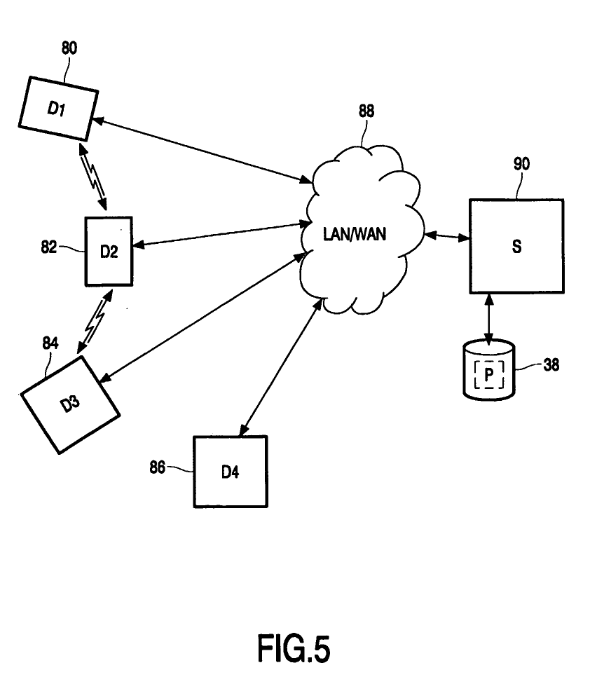

FIG. 5 illustrates an embodiment comprising a centralised policy.

In the Figures the same reference signs are generally used to refer to corresponding or similar features in modified and different embodiments. Other features and aspects of the present invention appear in the appended claims, which are incorporated herein by reference and to which the reader is now referred.

In the following embodiment a scenario in which a neighbour is able to request a volume control change of an adjacent neighbour's device is described. Those skilled in the art will recognise that the principle may be extended to the control of devices within a single home or apartment, or to apartments in close proximity (not necessarily adjacent) with each other.

FIG. 1 schematically represents an apartment or room 10 located beneath an upper apartment 20. The resident of apartment 10 owns devices 12 and 14 which are controllable by radio remote control 16. For example device 12 and 14 may represent a television (TV) and set-top box (STB) respectively. The radio remote control 16 may be in the form of the Philips iPronto™ for example.

The upper apartment 20 is shown having a device in the form of an audio stereo system 22, more commonly referred to as a “Hi-Fi”. The Hi-Fi 22 comprises audio output speakers 26, user interface control 24 and a display 28. The Hi-Fi 22 also comprises a radio module 30 to enable radio remote control and policy control. The resident of apartment 20 may, of course also own other personal and consumer electronic devices, including remote control units. One can expect similar sets of devices in neighbouring apartments (not shown).

In this embodiment the devices 12, 14, 16, 22 have communication means in the form of radio modules operating to the ZigBee™ radio standard (IEEE802.15.4). This is a low cost, low power spread spectrum radio standard designed by a consortia of companies (the ZigBee Alliance, www.zigbee.com) which has been designed with control and instrumentation applications in mind. ZigBee radio modules are expected to cost less than a few euros (about a dollar) and hence can be added to many current and future devices to provide radio communication. The range of such modules is about fifty metres or so. In the Figure, the Hi-Fi 22 includes an internal ZigBee radio module 30 with the remote control unit 16 including a ZigBee radio module 16a.

FIG. 2 is a block schematic of the Hi-Fi device 22. The device comprises a microprocessor 34 (μp) which under the operation of program instructions 35 (PRG), controls audio circuitry 32 to output audio via the speakers 26. The device furthermore comprises the ZigBee radio module 30 which itself comprises a microcontroller (mc) for controlling a transceiver (Tx/Rx). The module also includes memory (mem) for storing the ZigBee radio “stack” 40 which comprises in OSI fashion a physical (PHY) layer, medium access control layer (MAC), a network or link layer (NWK) and a layer corresponding to application code (AC). Radio messages or datagrams 42 comprising header fields 42a and payload or data fields 42b are transmitted and received over the air according to the stack 40 and application code (AC).

Hence a remote control unit 16 with a ZigBee module 16a may construct a datagram with a payload 42b containing a control request and transmit the datagram to the Hi-Fi device 22. The application code of the receiving module 30 may then extract the relevant data from the datagram and pass this onto the microprocessor 34. The microprocessor 34 has access to non-volatile storage 38 which in turn stores a control policy (P).

FIG. 3 shows an example data structure in the form of a policy table 50. In this example the policy comprises criteria t₁, t₂, t_{n,r} and tₕᵣ, with corresponding values 23:00, 09:00, (3, 15), and 5. t₁ and t₂ correspond to a time interval 23:00 to 09:00, which the residents of apartments 10,20 may have agreed to as being a “quiet time”. The criteria t_{n,r} refers to a number of requests (3) and a time interval r in which those requests are received, in this example 15 minutes. The criteria tₕᵣ corresponds to a threshold volume level which may be used by microprocessor 34 to determine whether the current output volume level should be adjusted, as will be described shortly.

In this embodiment in which the policy is stored within the first device 22, the criteria may be set by a manufacturer to provide a default policy. However, the criteria are preferably user definable by means of, for example, the user interface control 24 and display 28. This enables a “quiet time” of, for example 23:00 hours to 09:00 hours to be agreed upon by the residents of residences 10 and 20. Values for the agreed quiet time can then be input to the respective devices 22, 12,14 by each respective owner.

FIG. 4 illustrates a method by which the remote control 16 and Hi-Fi 22 interact to to enable adjustment of output volume control via the policy 50 during, for example agreed quiet periods. In step 60 (Tx/Rx) the user of remote control device 16, on being disturbed by loud music from the apartment above, causes a radio message 42 to be broadcast or transmitted from his radio remote control. The radio module 30 of Hi-Fi device 22 receives the message and application code (AC) 40 signals receipt of the message to microprocessor 34 of the Hi-Fi. Note that the message may be recognised as signifying a volume control “complaint” by including a predefined code in the payload 42b. ZigBee radio modules running appropriate application code may then signal the receipt of such a message to the microprocessor. Other ZigBee modules installed in for example a home lighting system would ignore such messages since such modules would conform to different service profiles and hence run alternative application code.

Returning to FIG. 4, the microprocessor in step 62 accesses the policy data stored in storage 38 and examines the criteria therein at step 64 (CRIT?). For example, in step 64 the processor 34 compares the current system time corresponding to the current time of day with “quiet period” criteria t1 and t2. Should the system time fall within the period t₁ to t₂ then processor 34 follows path 66 (Y) to step 68 (ADJ) where an adjustment to the volume output is effected by processor 34 and audio circuitry 32. Those skilled in the art of audio control will recognise that automatic control of the sound pressure level may be achieved in a Hi-Fi 22 with audio circuitry 32 comprising an integral amplifier and connected speakers 26.

Alternatively, the Hi-Fi may indicate to its owner that a request has been received, and that an adjustment according to policy is required, on display 28. The Hi-Fi owner may then decide whether to adjust the volume. Following such adjustment and action module 30 transmits an acknowledgement (ACK) to remote control 16 at step 70.

In the above example, if at step 64 (CRIT?) the time of day did not fall within criteria t₁ and t₂ then program flow continues via path 65 (N) to step 70 where the receipt of the message is acknowledged (ACK).

Hence, the owner of the Hi-Fi is informed that someone is complaining, and the output volume of the Hi-Fi is adjusted according to policy criteria.

Preferably, a log of requests and acknowledgements is stored by respective devices 16, 22. The logs may be accessed by a third party in the event of a dispute and used to corroborate the complaints and actions of those in dispute.

More complex policy criteria comparisons may be implemented at step 64. For example, the values associated with the criteria shown in FIG. 3 as t_{n,r} may indicate that an automatic adjustment is only effected when n messages are received within the time period r. Hence, the values of 3 and 15 stored in the example policy 50 indicate that three requests must be received within fifteen minutes of each other before the system performs an automatic volume adjustment. This has the advantage that accidentally transmitted messages are ignored. For example, the microprocessor 34 may notify via Hi-Fi display 28 that a request has been received. The user of the Hi-Fi may ignore this message. However, repeated requests within the period r indicate that other users really are being disturbed by the volume output, and hence an automatic adjustment is triggered at step 68.

Furthermore, the microprocessor may be programmed to adjust the volume at step 68 after comparing the current volume output with a threshold criteria (tₕᵣ) stored in the policy. The threshold may correspond to an agreed volume indication for that device (for example, arbitrary level of 50% of the range of the device). Hence a parent and child or neighbours may test what is acceptable in their environs with each other and agree on the appropriate threshold number to input to the policy.

Those skilled in the art will recognise that the microprocessor may be programmed to only adjust the volume when certain combinations of criteria are determined true (for example, the threshold is exceeded and it is a quiet period).

Another embodiment is illustrated in FIG. 5 which shows a number of devices 80 (D1), 82 (D2), 84 (D3), 86 (D4) linked via a local or wide area network 88 (LAN/WAN) to a server 90 which itself has access to storage 38 for storing a policy (P). The system of this embodiment is particularly suited to application within hotels or student halls of residence wherein a hotel owner or landlord may access and set the policy P on remote storage 38 via the central server 90. The link to the LAN and hence to the server and policy may be realised via conventional Ethernet hardware installed in the infrastructure of the hotel or hall of residence. In use, a first device (for example D3) receiving a request message from another device (for example D2) by radio means as described previously performs in general the method of FIG. 4. However, the first device accesses the centrally stored policy over the LAN at step 62.

This embodiment has an advantage in that the proprietor of the establishment (be it a hotel, hall of residence or otherwise) can alter and maintain the policy centrally. In a hall of residence for example, town meetings may be held in which the student residents and the proprietor negotiate quiet periods and other such policy criteria. Furthermore, the server may store a log of requests and acknowledgements including information as to whether the request was actioned (that is the volume was adjusted). This log can then be used in the case of a dispute involving residents who either ignore or abuse the policy.

In the above a method and system enabling control of a first device is described. Input criteria (which may be negotiated amongst users), form a stored policy, which in turn determines whether a request to control output is heeded or not. Whilst the above embodiments describe a system utilising

ZigBee radio communication for request messages, those skilled in the art will recognise that other radio protocols capable of forming network links such as Bluetooth™ or the IEEE802.11 standards family may be used. Furthermore, in a fixed building such as a hotel, messages between devices may be routed using the buildings network. In such a system, a simple “broadcast complaint” button in a room may be provided for sending messages, with devices having audio output reacting to received messages according to the stored policy as described herein.

From reading the present disclosure, other modifications will be apparent to persons skilled in the art. Such modifications may involve other features which are already known in the design, manufacture and use of audio control systems and component parts thereof and which may be used instead of or in addition to features already described herein without departing from the spirit and scope of the present invention.

1. A method for controlling the volume output of a first device (22), said device being operable to communicate with a second device (16) over a network link, the method comprising the second device sending a message (42) to the first device which receives said message, accesses a stored policy (50) and adjusts said output in dependence on the stored policy.

2. A method as claimed in claim 1, wherein the policy (50) contains criteria which includes the time of day to affect said adjustment.

3. A method as claimed in claim 1, wherein the policy (50) contains criteria which includes the number of received messages in a predetermined time interval to affect said adjustment.

4. A method as claimed in claim 1, wherein the policy (50) contains criteria which includes a threshold against which the current output volume is compared to affect said adjustment.

5. A method as claimed in claim 1, wherein following adjustment the output level is determined and included in an acknowledgement message (70) sent by the first device to the second device.

6. A method according to claim 1, wherein the stored policy criteria are user definable.

7. A system for controlling the volume output of a first device (22,80), said device being operable to communicate with a second device (16,82) over a network link, the second device having communication means (16a) for sending a message to the first device, the first device comprising communication means (30) for receiving the message, and processing means (34) for accessing a stored policy (38,50) and for controlling said output in dependence on the stored policy.

8. A system as claimed in claim 7, wherein said first and second device further comprise indicating means (28) for indicating to a user acknowledgement of transmitted and received messages.

9. A system as claimed in claim 7, wherein the communication means operate according to a selected one of ZigBee, Bluetooth or IEEE802.11 wireless radio protocols.

10. A system as claimed in claim 7, wherein the communication means operate according to a wired protocol.

11. A device (22,80) for use with the system of claim 7, said device comprising communication means (30) for receiving a message, means for accessing a stored policy (38,50) and processing means for controlling volume output in dependence on the stored policy.

12. Program code (35) on a carrier which when executed by processing means of a first device causes said first device to perform the method of claim 1.
